(19) United States
(12) Patent Application Publication
(10) Pub. No.: US 2024/0355540 A1
(43) Pub. Date: Oct. 24, 2024

(54) PCB-BASED STRANDED, TWISTED EXCITATION WINDINGS IN ROTARY TRANSFORMERS

(71) Applicant: BorgWarner Inc., Auburn Hills, MI (US)

(72) Inventors: Mostak Mohammad, Knoxville, TN (US); Jonathan Wilkins, Knoxville, TN (US); Emre Gurpinar, Knoxville, TN (US); Omer Onar, Knoxville, TN (US); Shajjad Chowdhury, Knoxville, TN (US); Randy H. Wiles, Strawberry Plains, TN (US)

(21) Appl. No.: 18/305,740

(22) Filed: Apr. 24, 2023

(51) Int. Cl. H01F 38/18; H01F 29/12; H01F 41/04; H05K 1/18

(52) U.S. Cl. CPC H01F 38/18; H01F 29/12; H01F 41/041; H05K 1/18; H05K 2201/1003

(57) ABSTRACT

Embodiments of the disclosure provide a rotary transformer (RT) that includes a printed circuit board (PCB) and a set of secondary windings integrated with the PCB. The set of secondary windings includes a plurality traces extending over a first region of the PCB and a second region of the PCB. The plurality of traces are organized in a first positional order in the first region of the PCB. The plurality of traces are organized in a second positional order in the second region of the PCB.

### CROSS REFERENCE TO RELATED APPLICATIONS

This application claims the benefit of an earlier filing date from U.S. Provisional Application Ser. No. 63/333,790 filed Apr. 22, 2022, the entire disclosure of which is incorporated herein by reference.

### BACKGROUND OF THE INVENTION

A wound-rotor synchronous machine (WRSM) is an electric motor having a rotor and a stator. The stator is the fixed part of the machine, and the rotor is the rotating part of the machine. The stator usually has a multi-phase winding, and the rotor is made with a field winding instead of permanent magnets. The rotor spins in a magnetic field, and the magnetic field can be produced by the windings or field coils. A field coil is an electromagnet used to generate a magnetic field in an electro-magnetic machine, typically a rotating electrical machine such as a motor or generator. It includes a coil of wire through which a current flows. In the case of a machine with field coils, a current must flow in the coils to generate the field, otherwise no power is transferred to or from the rotor. The process of generating a magnetic field by means of an electric current is called excitation. Field coils yield the most flexible form of magnetic flux regulation and de-regulation, but at the expense of a flow of electric current.

Conventionally, the rotor windings of a WRSM can be powered or excited using a slip ring and brush assembly systems. However, slip ring and brush assembly systems have disadvantages, including being inefficient at high speeds, frequently requiring maintenance, and being lossy overall, especially at high speeds due to the high contact resistances between the brush and the slip ring.

To avoid the shortcomings of slip ring and brush assembly excitation methods, wireless (or contactless) excitation or wireless power transfer systems have been developed. In general, wireless power transfer uses various technologies to transmit energy by means of electromagnetic fields (EMFs) without a physical link. In a wireless power transfer system, a transmitter device, driven by electric power from a power source, generates a time-varying EMF, which transmits power via mutual inductance (M) across space to a receiver device. The receiver device uses M to extract power from the EMF and supply the extracted power to an electrical load. Wireless power transfer provides power to electrical devices where interconnecting wires are inconvenient, hazardous, or are not possible. Wireless power techniques mainly fall into two categories, near field and far-field. In near field techniques, the time-varying EMF is generated using a variety of techniques, including resonant inductive coupling. Resonant inductive coupling is the near field wireless transfer of electrical energy between magnetically coupled coils that are part of a resonant circuit tuned to resonate at the same frequency as the driving frequency.

Rotary transformers (RTs) are a type of wireless power transfer system that can be used for the controlled wireless excitation of the rotor windings of a WRSM. An RT performs the same general function as a conventional transformer in that both transfer electrical energy from one circuit to another at the same frequency but different voltages. A conventional transformer works on the principle of electromagnetic induction, i.e., the electromotive force is induced in the closed circuit due to the variable magnetic field around it. An RT differs from a conventional transformer in that the RT geometry is arranged so that the primary windings and the secondary windings can be rotated with respect to each other with negligible changes in the electrical characteristics. In a known configuration, the RT can be constructed by winding the primary and secondary windings into separate halves of a cup core. The concentric halves face each other, with each half mounted to one of the parts that rotate with respect to one another. Magnetic flux provides the coupling from one half of the cup core to the other across an air gap, providing the “M” that transfers energy from the RT's primary windings to its secondary windings.

Known approaches to using RT systems to provide excitation for a WRSM can include a resonant tuning network, which is also known as a compensation network. A resonant tuning network can include circuit components (e.g., various combinations of resistors, inductors and/or capacitors) that enable the associated transformer to store oscillating electrical energy similar to a resonant circuit and thus function as a band pass filter, allowing frequencies near their resonant frequency to pass from the primary to secondary winding, but blocking other frequencies. The amount of M between the primary and the secondary windings, together with the quality factor (Q factor) of the circuit, determines the shape of the frequency response curve. Resonant circuits are often calls LC or LRC circuits because of the inductive (L), resistive (R), and capacitive (C) components used to form the resonant circuit. In material science, every material has its own natural frequency. If the external vibration is equal to the natural frequency, resonance occurs. In electrical science, impedance of the inductors and capacitors depends on the frequency. Capacitive impedance is inversely proportional to frequency while inductive impedance is directly proportional to the frequency. At a particular frequency both cancel each other. Such a circuit is called as resonant circuit, and that particular frequency is resonant frequency.

In conventional RT systems, the resonant tuning network (or compensation network) is provided on each of the stationary (or stator, or primary) side and the rotating (or rotary, or secondary) side of the WRSM. For the primary coil, a basic function of “compensation” is minimizing the input apparent power and/or minimizing the voltage-ampere (VA) rating of the power supply. For the secondary coil, the compensation cancels the leakage inductance of the secondary coil in order to maximize the transfer capability.

In general, electric motors can be relatively complex structures with parts that rotate at high speeds and generate high temperatures. Additionally, the use of various forms of electromotive force, EMFs, complex communications signals, high frequency (HF) communications signals, complex motor control operations, and the like, can add further complexity. Further, for many applications, the motor size and weight must be controlled. Thus, there is value in providing motor designs that prioritize providing compact size; reduced cost; simplicity in electrical, mechanical and thermal design; reduced eddy current losses; and an improved method for providing PCB-based winding that can effectively and efficiently process HF communications signals.

### BRIEF DESCRIPTION OF THE INVENTION

Embodiments of the disclosure provide a rotary transformer (RT) that includes a printed circuit board (PCB) and a set of secondary windings integrated with the PCB. The set of secondary windings includes a plurality traces extending over a first region of the PCB and a second region of the PCB. The plurality of traces are organized in a first positional order in the first region of the PCB. The plurality of traces are organized in a second positional order in the second region of the PCB.

Embodiments of the disclosure provide a method of forming a RT that includes a printed circuit board (PCB) and a set of secondary windings integrated with the PCB. The set of secondary windings includes a plurality traces extending over a first region of the PCB and a second region of the PCB. The plurality of traces are organized in a first positional order in the first region of the PCB. The plurality of traces are organized in a second positional order in the second region of the PCB.

### BRIEF DESCRIPTION OF THE DRAWINGS

FIG. 1 is a simplified block diagram illustrating a non-limiting example of an electric drive motor system having integrated power electronics in accordance with aspects of the disclosure;

FIG. 2 is a simplified block diagram illustrating a three-dimensional (3D) view and a front-side view of a non-limiting example of how a portion of a rotating-side of an electric machine can be configured to include integrated power electronics in accordance with aspects of the disclosure;

FIG. 3 depicts equations in accordance with aspects of the disclosure;

FIG. 4 is a simplified block diagram illustrating a non-limiting example of a portion of a RT in accordance with aspects of the disclosure;

FIG. 5 depicts an optimization equations in accordance with aspects of the disclosure;

FIG. 6A depicts a simplified block diagram illustrating a multi-stranded trace in accordance with aspects of the disclosure;

FIG. 6B depicts a simplified block diagram illustrating a multi-stranded trace in accordance with aspects of the disclosure;

FIG. 6C depicts a simplified block diagram illustrating a multi-stranded trace in accordance with aspects of the disclosure;

FIG. 7A depicts a PCB having untwisted turns;

FIG. 7B depicts a PCB having twisted strands in accordance with aspects of the disclosure;

FIG. 8A depicts a simplified block diagram illustrating full twisting in accordance with aspects of the disclosure;

FIG. 8B depicts a simplified block diagram illustrating partial twisting in accordance with aspects of the disclosure;

FIG. 9 depicts a PCB having twisted strands in accordance with aspects of the disclosure;

FIG. 10 is a simplified block diagram illustrating a non-limiting example of how layer-to-layer twisting can be implemented using via structures in accordance with aspects of the disclosure; and

FIG. 11 is a simplified block diagram illustrating a computer system operable to implement embodiments of the disclosure.

### DETAILED DESCRIPTION OF THE INVENTION

Embodiments of the disclosure provide a novel integrated power electronics system that can be used in an electric motor drive system having a wireless power transfer (or RT) network. The electric motor drive system can include an electric motor (e.g., a WRSM) having a stationary-side and a rotating-side. In embodiments of the disclosure, the integrated power electronics system can be implemented as an integrated mounting and/or communications structure with which selected portions of the motor and/or the wireless power transfer system can be integrated to provide improved physical support, improved electronic communications, and improved cooling. On the rotating-side, an instance of the integrated mounting and/or communications structure can be used to integrate secondary windings; rotating-side elements of the RT (if any); a rectifier; and various electronic connections between the secondary windings, the rotating-side elements of the RT, and the rectifier. On the stationary-side, an instance of the integrated mounting and/or communications structure can be used to integrate an inverter; stationary-side elements of the RT; primary windings; and various electronic connections between the inverter, the stationary-side elements of the RT, and the primary windings.

In some embodiments of the disclosure, the integrated mounting and/or communications structure can be implemented as a multi-layered printed circuit board (PCB) operable to incorporate within its layers primary windings, secondary windings, transistors (e.g., for the inverter), diodes (e.g., for the rectifier), wiring, and the like. On the rotating-side where cooling is needed, the PCB can incorporate an assembly region operable to house certain components (e.g., diodes for the rectifier) and cooling mechanisms for the housed components.

The PCB-based secondary windings have similarities with other PCB-based stationary planar inductor or transformer designs. However, the PCB-based secondary windings of an RT have two distinct features compared to the stationary planar transformer. Specifically, the primary core must have a considerably large gap to accommodate the secondary PCB structure; and the primary and secondary windings are physically separated, which means the conventionally used interleaving among the primary and secondary windings is not feasible for RT PCB-based applications. Therefore, the traditional design of multi-strand PCB-based windings causes significantly high loss in the RT application. In embodiments of the disclosure, an optimized multi-strand PCB-based windings design and optimization approach are proposed to minimize the loss and temperature rise.

Accordingly, the integrated mounting and/or communications structures (e.g., a PCB) and/or the an optimized multi-strand PCB-based windings design and optimization approach described herein provide technical benefits and technical effects. The secondary windings and the rectifier subsystems are assembled in the same PCB structure, which significantly simplifies the design, prototyping, and production of the associated RT. Embodiments of the disclosure also mitigate or eliminate the difficulties in terminations and interconnections between the rectifier and the secondary winding assemblies. Embodiments of the disclosure further allow the assembly region (e.g., the assembly region that houses diodes of the rectifier) can be directly mounted on the motor shaft using, for example, an aluminum support sleeve, which provides high mechanical robustness and simpler thermal management. Thus, in accordance with aspects of the disclosure, the integrated mounting and communications structure enables motor designs that prioritize compact size; reduced cost; simplicity in electrical, mechanical and thermal design; reduced eddy current losses; and the ability to efficiently and effectively process HF communications signals.

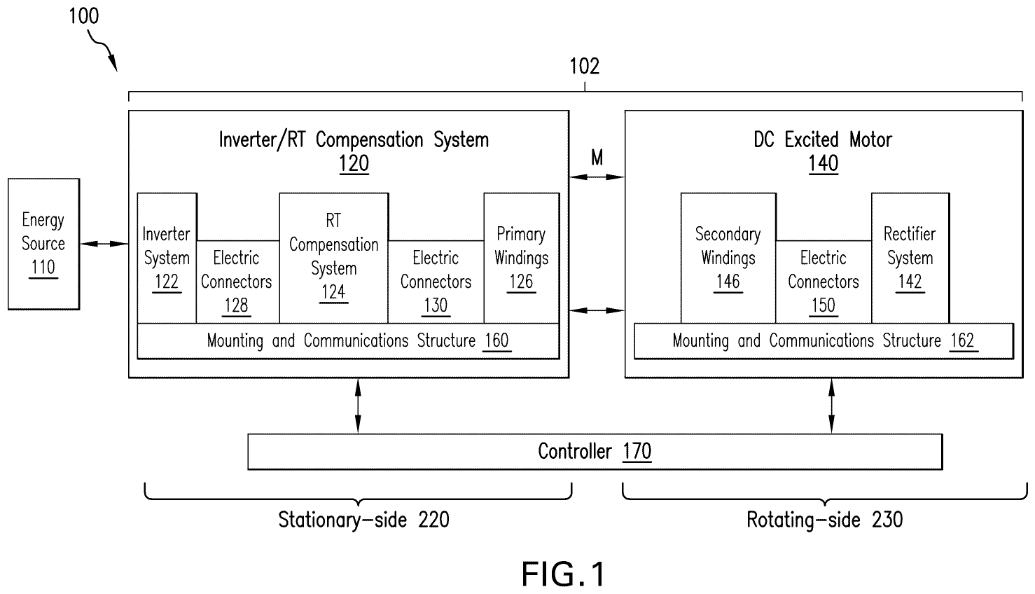

Turning now to a more detailed description of embodiments of the disclosure, FIG. 1 depicts a system 100 embodying aspects of the disclosure. The system 100 includes an energy source 110 electronically coupled to an electric motor drive system 102. The electronic motor drive system 102 includes an inverter/RT system 120, an DC excited motor 140, and a controller 170, configured and arranged as shown. In accordance with aspects of the disclosure, the inverter/RT system 120 includes an integrated mounting and communications structure 160 operable to integrate with an inverter system 122; an RT system 124; electric connectors 128 operable to electrically couple the inverter system 122 to the RT system 124; primary windings 126; and electric connectors 130 operable to electrically couple the RT system 124 to the primary windings 126. In accordance with aspects of the disclosure, the DC excited motor 140 includes an integrated mounting and communications structure 162 operable to integrate with secondary windings 146; a rectifier system 142; and electric connectors 150 operable to electrically couple the secondary windings 146 to the rectifier system 142. Although the inverter/RT system 120, the DC excited motor 140, and the controller 170 are depicted as separate components, it is understood that the inverter/RT system 120, the DC excited motor 140, and the controller 170 can be configured and arranged in any suitable combination. For example, the controller 170 can be incorporated within the inverter/RT system 120; the inverter/RT system 120 can be incorporated within the DC excited motor 140; and/or the inverter/RT system 120 and the controller 170 can be incorporated within the DC excited motor 140. Additionally, the system 100 includes a stationary-side (e.g., stator-side) 220 and a rotating-side (e.g., a rotor-side) 230. In general, the stationary-side 220 includes the primary windings 126 and the circuit elements to the left thereof, and the rotating-side 230 include the secondary windings 146 and the circuit elements to the right thereof.

The energy source 110 can be implemented in a variety of forms, including, for example as a battery. In some embodiments of the disclosure, the battery can be a battery pack having a set of one or more individual battery cells connected in series or in parallel and that operate under the control of one or more controllers, such as a battery control module (BCM) that monitors and controls the performance of the battery pack. The BCM can monitor several battery pack level characteristics such as pack current measured by a current sensor, pack voltage, and pack temperature, for example. The battery pack can be recharged by an external power source (not shown). The battery pack can include power conversion electronics operable to condition the power from the external power source to provide the proper voltage and current levels to the battery pack. The individual battery cells within a battery pack can be constructed from a variety of chemical formulations. Battery pack chemistries can include, but are not limited, to lead acid, nickel cadmium (NiCd), nickel-metal hydride (NIMH), lithium-ion or lithium-ion polymer.

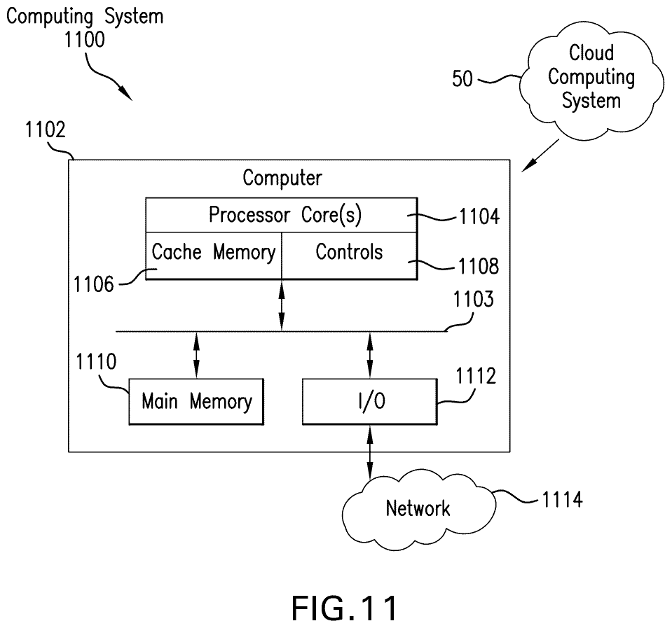

The inverter 122 can be a resonant inverter 122 electrically coupled between the energy source 110 and the DC excited motor 140 to transfer excitation energy from the energy source 110 through the RT system 124 and the primary windings 126 to the DC excited motor 140. More specifically, the resonant inverter 122 is operable to provide energy from the energy source 110 to the RT system 124 at a desired resonant frequency for purposes of providing excitation through the primary windings 126 to the DC excited motor 140. In embodiments of the disclosure, the resonant inverter 122 is operable to convert the DC voltage from the energy source 110 to AC current at the desired resonant frequency as required by the AC excited motor 140 and the RT system 124 for motor excitation. In embodiments of the disclosure, the resonant inverter 122 can be a full-bridge resonant inverter having four switches organized as two “phase legs.” Each phase leg can include two switches connected in series and between a positive DC rail and a negative DC rail. A phase node can be positioned between the two switches of each phase leg to provide the phases of an AC waveform output at a desired resonant frequency. In some embodiments of the disclosure, the resonant inverter 122 generates HF AC. The controller 170 is electronically coupled to the phase leg switches to control the on/off states of the switches, thereby controlling the frequency and phase of the AC waveform generated by the resonant inverter 122. The controller 170 includes a computing device, which includes a computer or a microprocessor configured and operable to execute software commands and programs, and which can include associated firmware, such that the controller is configured and operable to control the on/off switching operations of the resonant inverter 122. In embodiments of the disclosure, the controller 170 can be configured and arranged to include the features and functionality of the computing system 1100 (shown in FIG. 11). The controller 170 is also configured to send various control commands to the DC excited motor 140 to control, for example, torque and/or speed of the motor 140.

The DC excited motor 140 can be any eclectic motor design that is suitable for the work to be performed by the motor. Examples of work that can be done by motors in conventional automobile-based motor applications include operating or moving power windows; power seats; fans for the heater and the radiator; windshield wipers; and/or the engine of a vehicle having a hybrid-electric vehicle configuration. Regardless of the type of the DC excited motor 140, it relies on electromagnetism and flipping magnetic fields to generate mechanical power. A conventional implementation of the DC excited motor 140 includes five basic parts, namely, a stator; a rotor; a solid axle; coils; and a so-called “squirrel cage.” The winding of the stator in an DC excited motor is a ring of electromagnets that are paired up and energized in sequence, which creates the rotating magnetic field. The rotor in an DC excited motor does not have any direct connection to a power source, and it does not have brushes. Instead, it often uses the previously-described squirrel cage. The squirrel cage in an DC excited motor is a set of rotor bars connected to two rings, one at either end. The squirrel cage rotor goes inside the stator. When excitation power is sent through the stator, it creates an EMF. The bars in the squirrel cage rotor are conductors, so they respond to the flipping of the stator's poles, which rotates the rotor and creates its own magnetic field. The key to an induction motor, where the field of the rotor is induced by the field of the stator, is that the rotor is always trying to catch up. It is always looking for stasis, so it is rotating to find that steady state. However, the EMF produced by the stator is always going to be a little faster than the rotor's field. The spin of the rotor is creating the torque needed to create mechanical power to turn the wheels of a car or the blades of a fan. Some DC excited motors use a wound rotor (e.g., a WRSM), which is wrapped with wire instead of being a squirrel cage. In either case, there is only one moving part in an DC excited motor, which means there are fewer things that need to be replaced or maintained.

As noted, in some embodiments of the disclosure, the DC excited motor 140 can be a WRSM. A WRSM is a rotating electric motor having a rotor and a stator. The stator is the fixed part of the machine, and the rotor is the rotating part of the machine. The stator usually has a multi-phase winding, and the rotor is made with a field winding instead of permanent magnets. The rotor spins in a magnetic field, and the magnetic field can be produced by the windings or field coils. In the case of a machine with field coils, an excitation current must flow in the coils to generate the field, otherwise no power is transferred to or from the rotor. Field coils yield the most flexible form of magnetic flux regulation and de-regulation, but at the expense of a flow of electric current. Conventionally, the rotor winding of a WRSM can be powered or excited with a slip ring and brush assembly. However, slip ring and brush systems have disadvantages, including being inefficient at high speeds, frequently requiring maintenance, and being lossy overall, especially at high speeds due to the high contact resistances between the brush and the slip ring systems.

To avoid the shortcomings of slip ring and brush assembly excitation methods, the RT compensation system 124, the primary windings 126, and the secondary windings 146 are operable to provide wireless excitation or wireless power transfer from the stationary-side 220 to the rotating-side 230. The secondary windings 146 are sufficiently close to the primary windings 126 to be within an EMF generated by the primary windings 126 such that M is between the primary windings 126 and the secondary windings 146. The secondary windings uses M to generate an AC charging signal, and the rectifier system 142 converts the AC charging signal to a DC charging signal that is provided to the rotor (now shown separately from the motor 140. In some embodiments of the disclosure, the RT compensation system 124 can be implemented as a specially designed only-stationary-side RT compensation system 124. In general, the RT is a circuit and method for wireless power transfer to the secondary windings of a WRSM for controlled excitation. An RT is essentially the same as a conventional transformer in that it transfers electrical energy from one circuit to another at the same frequency but different voltage. In general, a conventional transformer works on the principle of electromagnetic induction, i.e., the electromotive force is induced in the closed circuit due to the variable magnetic field around it. An RT differs from a conventional transformer in that the RT's geometry is arranged so that the primary windings and secondary windings can be rotated with respect to each other with negligible changes in the electrical characteristics. In a known configuration, the RT can be constructed by winding the primary and secondary windings into separate halves of a cup core. The concentric halves face each other, with each half mounted to one of the parts that rotate with respect to one another. Magnetic flux provides the coupling from one half of the cup core to the other across an air gap, providing the “M” that couples energy from the RT's primary windings to its secondary windings.

In conventional RT designs, a resonant tuning network (or compensation network) is provided on each of the stationary (or primary) side and the rotating (or secondary) side of the WRSM. RT designs that have resonant circuit components on both the stationary-side and the rotating-side of the WRSM are difficult to implement. For example, it is difficult to, in practice, place a resonant tuning network or compensation circuitry on the secondary-side due to very limited rotor space and the high-temperature rotor operating conditions that exceed the temperature rating of commercially available compact capacitors. Moreover, having a resonant tuning capacitor on the secondary-side increases the complexity of the rotating part, increases the mechanical mass, increases the inertia, and reduces mechanical reliability, especially at high rotational speeds.

The only-stationary-side implementation of the RT compensation system 124 addresses the difficulties associated with actually implementing (i.e., building and using) conventional RT designs that include double-sided compensation networks by providing the benefits of wireless power transfer without the difficulties associated with providing compensation circuitry on a rotating-side of an DC excited motor 140 (e.g., a WFSM). More specifically, the only-stationary-side implementation of the RT compensation system 124 is operable to deliver rotor excitation current from the primary windings 126 to the secondary windings 146 wirelessly, thereby eliminating the brush and slip ring maintenance issues, as well as the inefficiencies, fabrication challenges, and design drawbacks associated with brush and slip ring systems.

In aspects of the disclosure, the only-stationary-side implementation of the RT compensation system 124 accounts for having no resonant tuning capacitor on the secondary side by providing an extra resonant tuning capacitor (i.e., one of the resonant tuning capacitors of an only-stationary-side resonant LCC) on the primary side and adjusting the two primary side resonant tuning capacitors so that the uncompensated secondary side does not impose inefficiencies or other drawbacks on the RT compensation system 124. In embodiments of the disclosure, an only-stationary-side LCC design methodology is provided that includes reflecting the impendence and/or inductance of the secondary side to the primary side, and the leakage inductance of this secondary windings 146 is tuned on the primary side. In general, a reflected impedance (or inductance) is the part of the impedance of a circuit (e.g., circuit A) that is due to the influence another coupled circuit (e.g., circuit B). In embodiments of the disclosure, this can be accomplished by deriving the equivalent circuit models of the system 100, as well as the overall impedance model of the system 100, which allows the reflective impedance from the secondary to the primary to be computed. A further simplification is applied to the derived equivalent circuit models so the overall impedance seen by the resonant inverter 122 can be calculated. In order to tune this overall impedance to a unity power factor, a tuning capacitor of the LCC design is recalculated. Thus, the only-stationary-side implementation of the RT compensation system 124 eliminates the need for capacitor tuning on secondary side, and the need for a secondary side resonant tuning capacitor(s) and tuning thereof, by providing additional primary side tuning components (e.g., a resonant tuning capacitor(s)) and adjusting the values of the tuning components on the primary side.

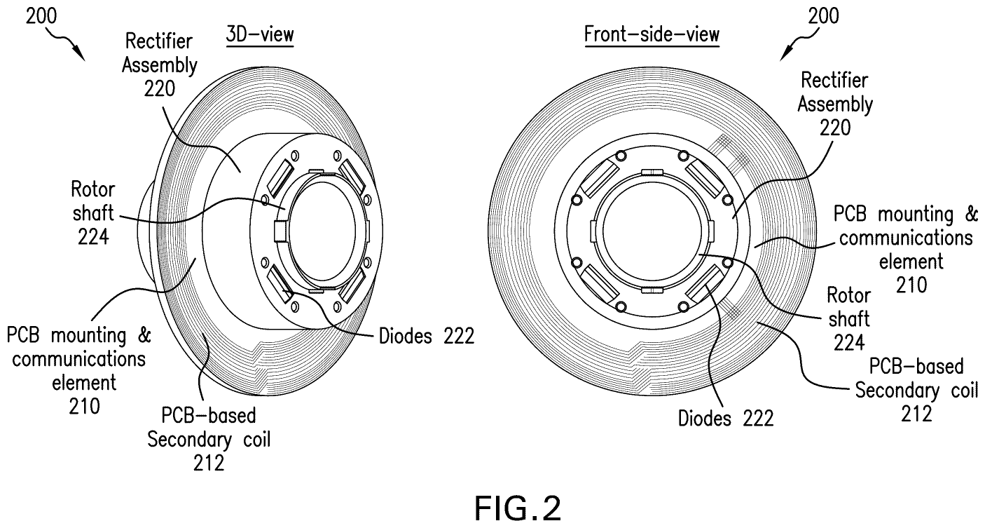

FIGS. 2-10 depict examples of how various embodiments of the disclosure can be designed and made in accordance with aspects of the disclosure. For the sake of brevity, conventional techniques related to making and using aspects of the disclosure may or may not be described in detail herein. In particular, various aspects of fabricating PCBs, electrical components, electronic connections, bonding techniques, and the like that can be used to implement the various technical features described herein are well known. Accordingly, in the interest of brevity, many conventional implementation details are only mentioned briefly herein or are omitted entirely without providing the well-known system and/or process details.

Additionally, although FIG. 2 focuses on an example implementation of the integrated mounting and communications structure 162, the secondary windings 146, the electric connectors 150, and the rectifier system 142 shown in FIG. 1, substantially the same structure options and fabrications option apply to the integrated mounting and communications structure 160, the inverter system 122, the electric connectors 128, the RT compensation system 124, the electric connectors 130, and the primary windings 126 shown in FIG. 1.

FIG. 2 depicts additional details of how the integrated mounting and communications structure 162, the secondary windings 146, the electric connectors 150, and the rectifier system 142 (all shown in FIG. 1) can be implemented as an integrated windings/rectifier 200 in accordance with aspects of the disclosure. FIG. 2 depicts a 3D-view and a front-side-view of the windings/rectifier 200, which includes a PCB mounting/communication element 210, a PCB-based secondary coil 212, a configuration of diodes 222 arranged as a rectifier circuit, a rectifier assembly 220, and a rotor shaft 224, configured and arranged as shown. In general, a rotor shaft is a central component of an electric motor. The rotor shaft is the carrier shaft for the laminated core of the rotor and thus transmits the electrically induced torque via a corresponding command from the controller 170 (shown in FIG. 1). The PCB mounting/communication element 210 is an example implementation of the integrated mounting and communications structure 162; the PCB-based secondary coil 212 is an example implementation of the secondary windings 146; and the diodes 222 are configured to form a rectifier circuit that is an example implementation of the rectifier system 142. The PCB mounting/communications element 210 is a multi-layer PCB structure operable to incorporate in one or more of its layers the PCB-based secondary coil 212 (with or without a magnetic core) formed as traces, along with some or all of the electric connectors 150 (shown in FIG. 1). In some embodiments of the disclosure, the rectifier diodes 222 can be incorporated within one or more layers of the PCB mounting/communications element 210. In some embodiments of the disclosure, the rectifier diodes 222 are mounted within a rectifier assembly 220 that is mounted (e.g., through soldering or another suitable bonding mechanism) to an exposed surface of the PCB mounting/communications element 210. In accordance with aspects of the disclosure, the PCB mounting/communications element 210 and the rectifier assembly 220 are physically bonded to one another such that they function as a unitary structure that houses the PCB-based secondary coil 212, the rectifier diodes 222 and portions of the electric connectors 150. In some embodiments of the disclosure, the rectifier assembly 222 can be configured to include suitable thermal management elements operable to dissipate heat generated on the rotating-side 230 during operation of the electric motor 140 (shown in FIG. 1).

In alternative configurations of the windings/rectifier structure 200, the PCB mounting/communications element 210 can be configured and arranged such that it is physically mounted (e.g., through soldering or another suitable bonding mechanism) to an exposed outer surface of the rectifier assembly 220; and the rectifier assembly 220 is physically mounted (e.g., through soldering or another suitable bonding mechanism) to an exposed outer surface of the rotor shaft 224. In another alternative configuration of the windings/rectifier structure 200, the PCB mounting/communications element 210 can be configured and arranged such that it can be physically mounted (e.g., through soldering or another suitable bonding mechanism) to an exposed outer surface of the rotor shaft 224; and the rectifier assembly 220 is also physically mounted (e.g., through soldering or another suitable bonding mechanism) to an exposed outer surface of the rotor shaft 224. In some embodiments of the disclosure, the rectifier assembly 220 is also physically mounted (e.g., through soldering or another suitable bonding mechanism) to an exposed surface of the PCB mounting/communications element 210.

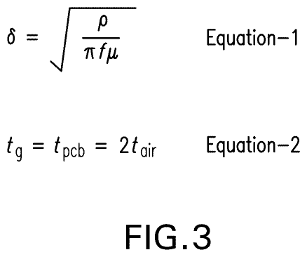

The PCB-based secondary windings 212 have similarities with other PCB-based stationary planar inductor or transformer designs. However, the PCB-based secondary windings of an RT have two distinct features compared to the stationary planar transformer. Specifically, the primary core must have a considerably large gap to accommodate the secondary PCB structure; and the primary and secondary windings are physically separated, which means the conventionally used interleaving among the primary and secondary windings is not feasible for RT PCB-based applications. Therefore, the traditional design of multi-strand PCB-based windings causes significantly high loss in the RT application. FIGS. 3-10 depict an optimized multi-strand PCB-based windings design and optimization approach operable to minimize the loss and temperature rise.

Known PCB-based secondary winding configurations for RT applications experience high copper loss due to skin effects, proximity effects, and eddy current losses. A large gap in the ferrite core causes significantly high leakage flux, further increases losses, and results in temperature rises in the PCB. Segregating the copper winding traces into multiple parallel paths reduces the skin effect and eddy current loss. However, the conventional winding design that uses parallel traces experience unbalanced inductances among the stranded current paths and causes unbalanced loss and thermal hotspots in the PCB.

At HF, the current in the winding conductors tends to concentrate near the outer boundaries of the conductor, which is known as the skin effect. The skin effect is characterized by the skin depth, which is expressed as Equation-1 (shown in FIG. 3), where p is the electrical resistivity of the material, f is the operating frequency, and u is the magnetic permeability of the material. If the skin depth is much smaller than the conductor size, then the effective resistivity of the conductor become high due to current crowding near its outer boundaries and causes high loss. Copper is widely used as the winding material in winding designs, including PCB-based winding designs. Considering conventional engineering constraints, RTs are conventionally operated between about 20 kHz to about 100 kHz operating frequency. From Equation-1 (shown in FIG. 3), it can be seen that the skin depth of copper is about 0.206 mm at about 100 kHz and about 0.461 mm at about 20 kHz. In order to substantially mitigate the skin effect, the width and thickness of the conductor should be less than twice the skin depth 28. Therefore, for a stranded conductor design, each of the copper strands should be narrow and thin enough to mitigate the skin effect. For example, at about 100 kHz, the thickness and width of the copper winding/trace should be lower than about 0.4 mm.

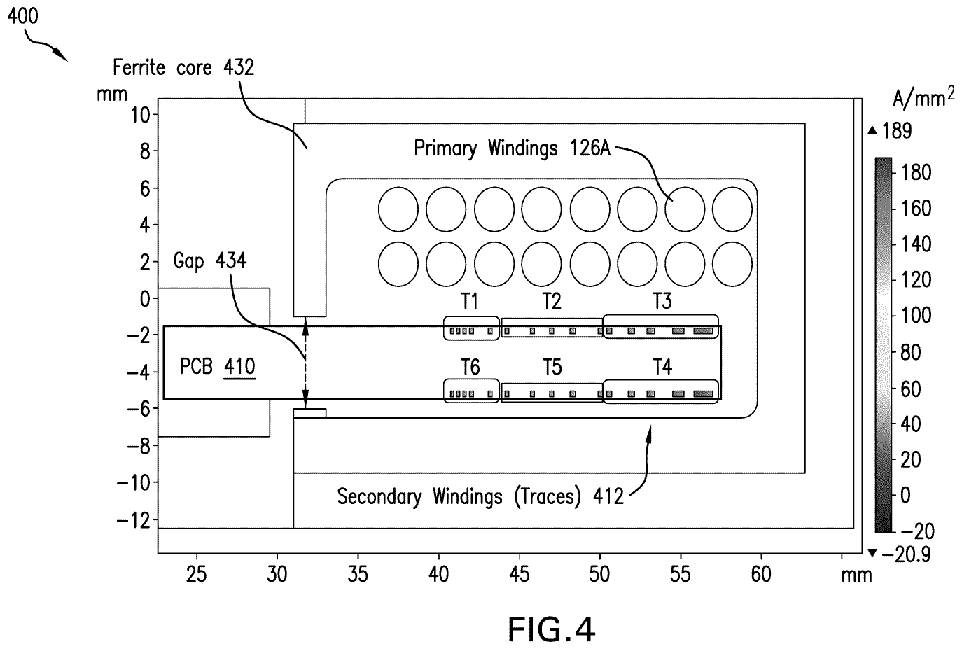

A gap (e.g., gap 434 shown in FIG. 4) is kept in the core (e.g., core 432 shown in FIG. 4) of a portion of an RT (e.g., 400 shown in FIG. 4). The gap is large enough to accommodate the thickness of a rotating PCB board and the gaps (i.e., air-gaps) between the PCB board and the ferrite core for free rotation. The gap can be expressed using Equation-2 (shown in FIG. 3), where t_{pcb} is the thickness of the PCB board, and tₐᵢᵣ is the gap between the PCB board and the core. It is assumed that the air-gap is substantially the same on both sides of the PCB. A significantly high circulating current occurs on the traces near the gap due to the higher leakage flux. Therefore, from the magnetic perspective, a lower r_{g} provides lower leakage flux and therefore lower eddy current losses in the PCB. However, from the mechanical perspective, a minimum value of PCB thickness is required to run the PCB at high-speed rotation, which can go up to about 25000 revolutions per minute (RPM) or even higher. Similarly, a minimum air-gap is needed between the PCB and core to maintain the needed clearance taking into account vibrations, manufacturability, installation tolerance, and high-speed deformation of the PCB. The gap t_{g} typically ranges from between about 3 mm to about 10 mm depending on the PCB material, operating speed, mechanical tolerances, operating temperature, and the like. Under such a magnetic gap, the leakage flux near the air-gap can be significantly high, and the PCB winding traces would need to be designed and optimized accordingly to minimize the eddy current. Embodiments of the disclosure, design methodologies and resulting structures for the thickness, width, and positions of individual traces are optimized to minimize the eddy current, loss and the temperature rise in the PCB.

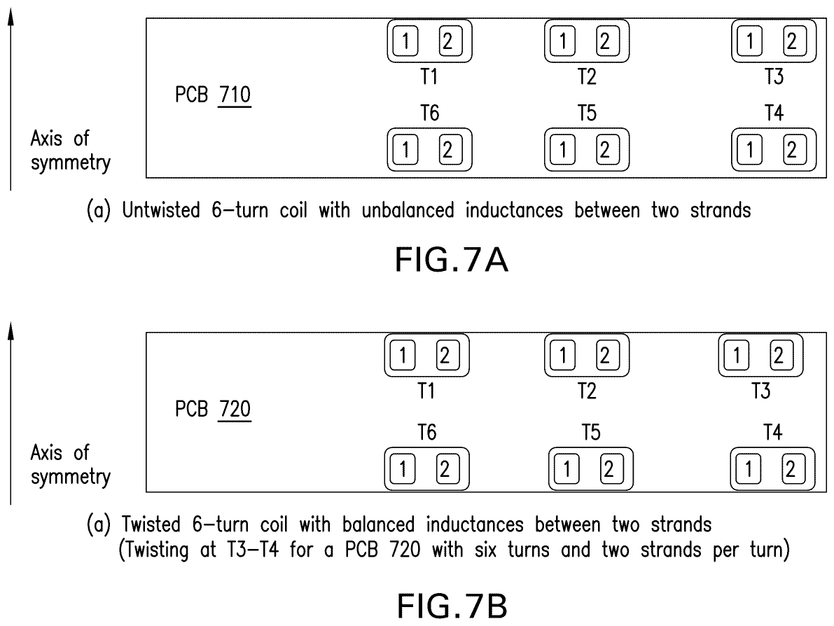

FIG. 7A depicts an example of a PCB 710 having an “untwisted” 6-turn windings (T1, T2, T3, T4, T5, T6) with unbalanced induction between two strands (strand-1 and strand-2). In FIG. 7A, it can be observed that the overall length of strand-1 will be less than the length of strand-2 due to the lower radius of the strand-1 on each turn. Therefore, the resistance and the inductance of the strand-1 will be less than the strand-2. Hence, the total current of the turns will be distributed unequally among strand-1 and strand-2, with strand-1 carrying higher current than the strand-2. Consequently, the loss and temperature of strand-1 will be higher than strand-2. This phenomenon worsen as the number of strands per turn increases, which results in larger differences between the radius of the outer strands compared to the inner strands.

In embodiments of the disclosure, a stranded twisted winding to balance the mean length per strand (MLS) and current among the strands of the windings is disclosed. Each of the strands is designed to minimize the loss and maximum temperature in the PCB-based coil windings. The proposed design and optimization method minimizes the skin effect, proximity effect, and the eddy current losses due to the leakage magnetic field and cross-coupling between neighboring turns and strands. The number of layers of the PCB, the thickness of the PCB, the thickness of the inner and outer copper layers, the number of strands per turn, the width, and the position of each strand are the sensitive design and optimization parameters. FIGS. 4-10 depict details of a design methodology in accordance with aspects of the disclosure. The number of layers and the copper thickness in each layer are two design parameters used herein to minimize the loss and temperature of the PCB. The maximum thickness of the copper layer is limited by the effect of skin depth. At about 100 kHz, the copper thickness can be up to about 15 Oz, while for about 20 kHz it can be even thicker. However, thicker copper layers are challenging and costly to manufacture. On the other hand, if a lower copper thickness is chosen, such as 4 Oz, then a higher number of layers can be implemented to fabricate the PCB in a cost effective way. As the number of PCB layer increases, the number of strands per turn increases proportionally, and this reduces the loss in the PCB. However, the maximum number of layers is limited by the structural integrity of the PCB.

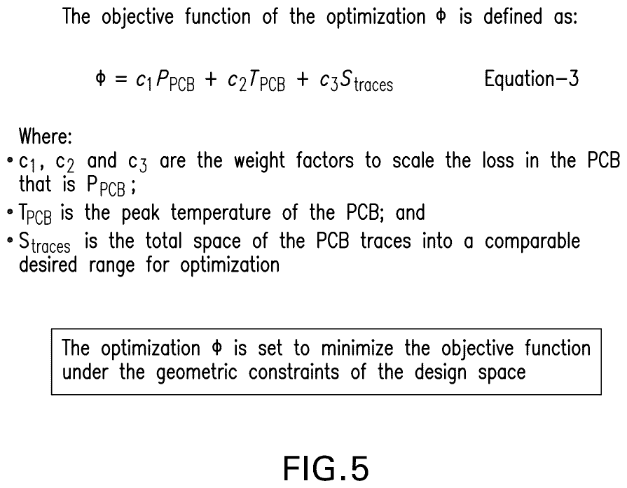

FIG. 4 depicts a portion of an RT 400 in accordance with aspects of the disclosure. The RT 400 includes a rotatable PCB 410, secondary windings 412 integrated with the rotatable PCB 410, primary windings 126A, a ferrite core 432, and a gap 434, configured and arranged as shown. The loss and temperature rise of the PCB secondary windings 412 are sensitive to the position and width of the strands T1 through T6, the number of strands per turn, and the thickness of the copper layers of the PCB 410. All the turns can have the same number of strands or different number of strands, depending on their relative position and overall loss distribution in the PCB. For example, a higher number of strands is beneficial for the turns close to the gap, compared to the turns that are away from the gap. The RT 400 shown in FIG. 4 depicts a 6-turn PCB design with 5 strands per turn. The traces are placed only on two of the PCB layers. An additional two layers (not shown) are required to implement the twisting T1-T2, T2-T3, T4-T5, and T5-T6. Both the trace width and the trace position are optimized for this design. The result shows that the widths of the strands closer to the gap 434 are much narrower than the widths of the strands that are further away from the gap 434. FIG. 5 depicts Equation-3, which is an optimization equation in accordance with aspects of the disclosure. Using Equation-3, the strands of the PCB 410 are optimized to minimize the total power losses in the PCB 410, minimize the peak temperature rise of in the PCB 410, and keep the traces away from the gap 434. In general, Equation-3 is an optimization objective function. The objective function set in the modeling software explores different design configurations to minimize the total power loss and peak temperature rise while trying to keep the traces away from the airgap. Accordingly, Equation-3 can be used in modeling software running on the computer system 1100 (shown in FIG. 11) to achieve optimization targets.

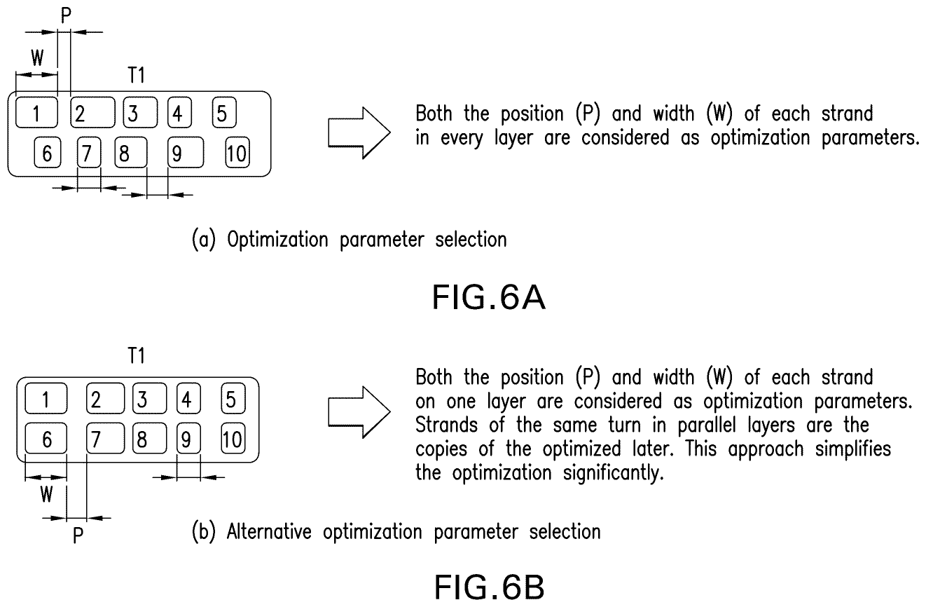

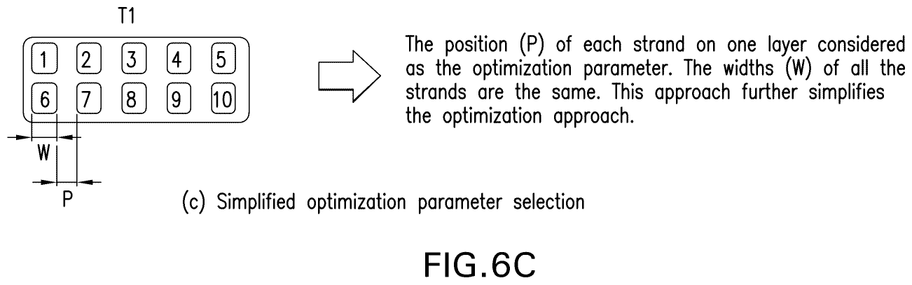

Both the width (W) and the position (P) of the traces can be optimized. In the optimization process, the width of each of the strand can be entered as an optimization parameter. However, that increases the optimization time significantly, as the processing time increases. FIGS. 6A, 6B, and 6C depict example optimizations approaches in accordance with aspects of the disclosure. Additionally, the number of layers and the thickness of each layer are two optimization parameters used in embodiments of the disclosure to determine the overall loss and temperature rise of the PCB 410. FIG. 6A depicts a trace T1 illustrating an example in which both the position (P) and the width (W) of each strand in every layer are considered as optimization parameters. FIG. 6B depicts another instance of the trace T1 illustrating an example in which both the position (P) and the width (W) of each strand on one layer are considered as optimization parameters. Strands of the same turn in parallel layers are the copies of the optimized layer. This approach simplifies the optimization significantly. FIG. 6C depicts another instance of the trace T1 illustrating an example in which both the position (P) of each strand on one layer IS considered as optimization parameters. The widths (W) of all the strands are the same. This approach further simplifies the optimization approach.

Twisting functionality associated with aspects of the disclosure will now be described. A winding design in accordance with aspects of the disclosure can be categorized into two topologies. The first topology is multiple turns per layer distributed spirally, and the second topology is only one turn with multiple strands placed over each layer. With respect to the first topology, twisting can be introduced at different places in the winding to balance the currents among the strands in a winding. FIG. 7A shows the axially-symmetric cross-sectional view of a PCB 710 with 6 turns, where the winding has two strands. The six circular turns are wound as T1-T2-T3-T4-T5-T6. To make the mean length per strand (MLS) about the same, this disclosure proposes a turn-to-turn-twisting among the strands. For example, if the relative positions of the strands are reversed as shown in the PCB 720 of FIG. 7B, the MLS of strand-1 and strand-2 will be about the same. This reversing of the relative strand positions is referred to herein as “twisting.” Twisting can be introduced at different positions of the winding. For example, the following twisting options provide a balanced MLS in the following system. For option 1, apply two twistings—one between T1 and T2; and another between T4 and T5. For option 2, apply two twisting—one between T2 and T3; and another between T4 and T5. For option 3, apply four twistings—one between T1 and T2; one between T4 and T5; one between T2 and T3; and one between T4 and T5. For option 4, apply one twisting between T3 and T4.

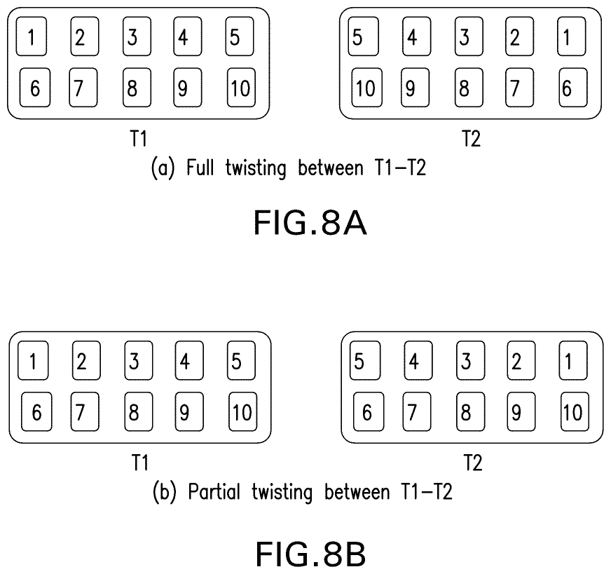

As the number of turns increase, options for twisting increase to balance the MLS among the strands. Among the four twisting options as mentioned above, the fourth one has technical benefits over the others. The balanced MLS can be achieved by only one twist from T3 to T4, which is at the mid-turn, when the traces are moving from one side of the PCB to the other side. Also, this configuration requires no additional PCB layer for twisting, while other options (option 1-3) require two additional layers in the PCB to implement the twisting. Similarly, when there are only two strands, there is only one option for strand-twisting-order, which is reversing the position of strand-1 and strand-2. As the number of strands increase, the options for repositioning the strands also increase. Reversing the order of all the strands is referred to herein as “full twist” (an example of which is shown in FIG. 8A) and repositioning a part of the strand is referred to herein as partial twisting (an example of which is shown in FIG. 8B). As the strands of each turn span for more than one layer, the options and flexibility of partial twisting become higher. Like full twisting, the same MLS can be achieved by applying multiple partial twisting, which could be beneficial while placing vias (extending from on PCB layer to another PCB layer) to realize the twist physically in the PCB design.

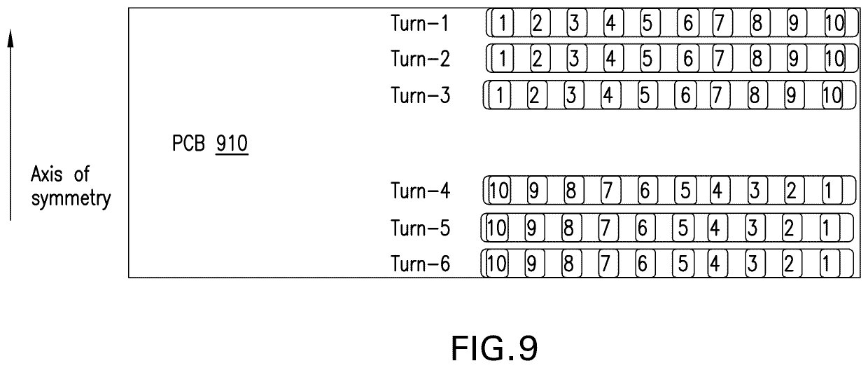

As previously noted herein, a winding design in accordance with aspects of the disclosure can be categorized into two topologies. The first topology is multiple turns per layer distributed spirally, and the second topology is only one turn with multiple strands placed over each layer. With respect to the second topology, FIG. 9 depicts a PCB 910 having a winding design configured and arranged to include one turn (10 strands) on each layer, and a twisting is introduced between Turn-3 and Turn-4. Such a twist can be introduced without using any additional layers. For the PCB 910, each layer contains one turn. A full-twisting is introduced between Turn-3 and Turn-4, which balances the inductance and MLS of the strands. This design does not require any additional layer to fit the twisting. The twisting can be sequentially applied as the traces drop from layer 3 to layer 4. The MLS can be balanced by only one twisting for even and odd number of the twists. Alternatively, instead of one twisting, two or more twisting can be applied to achieve easier MLS balancing. The position, width, and thickness of the traces, and number of layers are subject of optimization following the proposed optimization method illustrated in FIGS. 4-6C and described previously herein.

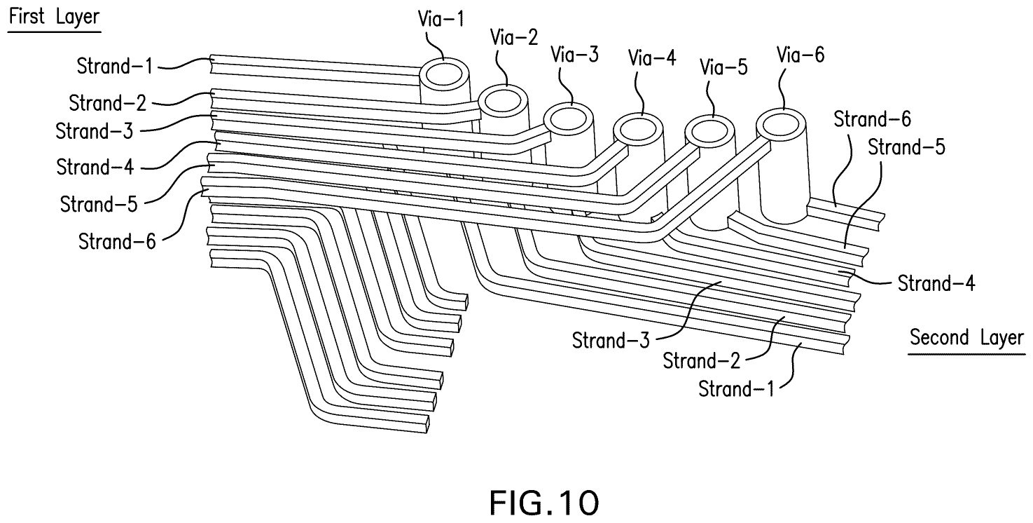

FIG. 10 is a diagram illustrating an example of how a strand twisting operation can be implemented from a first layer of a PCB to a second lower layer of the PCB using vias in accordance with aspects of the disclosure. As shown, at the first layer, Strand-1 is physically and electrically coupled to Via-1; Strand-2 is physically and electrically coupled to Via-2; Strand-3 is physically and electrically coupled to Via-3; Strand-4 is physically and electrically coupled to Via-4; Strand-5 is physically and electrically coupled to Via-5; and Strand-6 is physically and electrically coupled to Via-6. Via-1 transitions Strand-1 from the first layer of the PCB to the second layer of the PCB, and further changes Strand-1 from occupying a first and outermost position at the first layer to occupying a sixth and innermost position at the second layer of the PCB. Via-2 transitions Strand-2 from the first layer of the PCB to the second layer of the PCB, and further changes Strand-2 from occupying a second position at the first layer to occupying a fifth position at the second layer of the PCB. Via-3 transitions Strand-3 from the first layer of the PCB to the second layer of the PCB, and further changes Strand-3 from occupying a third position at the first layer to occupying a fourth position at the second layer of the PCB. Via-4 transitions Strand-4 from the first layer of the PCB to the second layer of the PCB, and further changes Strand-4 from occupying a fourth position at the first layer to occupying a third position at the second layer of the PCB. Via-5 transitions Strand-5 from the first layer of the PCB to the second layer of the PCB, and further changes Strand-5 from occupying a fifth position at the first layer to occupying a second position at the second layer of the PCB. Via-6 transitions Strand-6 from the first layer of the PCB to the second layer of the PCB, and further changes Strand-6 from occupying a sixth position at the first layer to occupying a first position at the second layer of the PCB.

Accordingly, it can be seen from the foregoing detailed description that the integrated mounting and/or communications structures (e.g., a PCB) described herein provide technical benefits and technical effects. The secondary windings and the rectifier subsystems are assembled in the same PCB structure, which significantly simplifies the design, prototyping, and production of the associated RT. Embodiments of the disclosure also mitigate or eliminate the difficulties in terminations and interconnections between the rectifier and the secondary winding assemblies. Embodiments of the disclosure further allow the assembly region (e.g., the assembly region that houses diodes of the rectifier) can be directly mounted on the motor shaft using aluminum support sleeve, which provides high mechanical robustness and simpler thermal management. Thus, in accordance with aspects of the disclosure, the integrated mounting and communications structure enables motor designs that prioritize compact size; reduced cost; simplicity in electrical, mechanical and thermal design; and reduced eddy current losses

FIG. 11 illustrates an example of a computer system 1100 that can be used to implement the computer-based components in accordance with aspects of the disclosure. The computer system 1100 includes an exemplary computing device (“computer”) 1102 configured for performing various aspects of the content-based semantic monitoring operations described herein in accordance aspects of the disclosure. In addition to computer 1102, exemplary computer system 1100 includes network 1114, which connects computer 1102 to additional systems (not depicted) and can include one or more wide area networks (WANs) and/or local area networks (LANs) such as the Internet, intranet(s), and/or wireless communication network(s). Computer 1102 and additional system are in communication via network 1114, e.g., to communicate data between them.

Exemplary computer 1102 includes processor cores 1104, main memory (“memory”) 1110, and input/output component(s) 1112, which are in communication via bus 1103. Processor cores 1104 includes cache memory (“cache”) 1106 and controls 1108, which include branch prediction structures and associated search, hit, detect and update logic, which will be described in more detail below. Cache 1106 can include multiple cache levels (not depicted) that are on or off-chip from processor 1104. Memory 1110 can include various data stored therein, e.g., instructions, software, routines, etc., which, e.g., can be transferred to/from cache 1106 by controls 1108 for execution by processor 1104. Input/output component(s) 1112 can include one or more components that facilitate local and/or remote input/output operations to/from computer 1102, such as a display, keyboard, modem, network adapter, etc. (not depicted).

A cloud computing system 50 is in wired or wireless electronic communication with the computer system 1100. The cloud computing system 50 can supplement, support or replace some or all of the functionality (in any combination) of the computer system 1100. Additionally, some or all of the functionality of the computer system 1100 can be implemented as a node of the cloud computing system 50.

The various winding optimization and twisting design operations can be implemented by a computer aided design (CAD) system operable to perform computations, circuit modeling, and circuit simulation operations in accordance with aspects of the disclosure. In accordance with aspects of the disclosure, the previously-described CAD system can be implemented using the computer system 1100 (shown in FIG. 11) to run CAD software applications operable to perform the various computations and algorithms described herein.

The various components/modules of the systems illustrated herein are depicted separately for ease of illustration and explanation. In embodiments of the disclosure, the functions performed by the various components/modules/models can be distributed differently than shown without departing from the scope of the various embodiments of the disclosure describe herein unless it is specifically stated otherwise.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

Aspects of the disclosure can be embodied as a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the disclosure has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the disclosure without departing from the essential scope thereof. Therefore, it is intended that the invention not be limited to the particular embodiment disclosed as the best mode contemplated for carrying out this invention, but that the invention will include all embodiments falling within the scope of the claims.

What is claimed is:

1. A rotary transformer (RT) comprising:
a printed circuit board (PCB); and
a set of secondary windings integrated with the PCB;
wherein the set of secondary windings comprises a plurality traces extending over a first region of the PCB and a second region of the PCB;
wherein the plurality of traces are organized in a first positional order in the first region of the PCB; and
wherein the plurality of traces are organized in a second positional order in the second region of the PCB.

2. The RT of claim 1 wherein the PCB further comprises a first one of the plurality of traces.

3. The RT of claim 2, wherein the first one of the plurality of traces has a first positional location in the first positional order.

4. The RT of claim 3, wherein the first one of the plurality of traces has a second positional location in the second positional order.

5. The RT of claim 4, wherein the first positional location in the first positional order is different from the second positional location in the second positional order.

6. The RT of claim 5, wherein the RT further comprises a first via element.

7. The RT of claim 6, wherein a first end of the first via element is physically and electrically coupled to the first one of the plurality of traces in the first region.

8. The RT of claim 7, wherein a second end of the first via element is physically and electrically coupled to the first one of the plurality of traces in the second region.

9. The RT of claim 8, wherein:
the first region comprises a first layer of the PCB; and
the second region comprises a second layer of the PCB.

10. The RT of claim 1, wherein:
each of the plurality of traces comprises a plurality of strands;
each of the plurality of strands comprises a width (W) and a position (P) within its associated trace;
W and P are optimized to minimize inductance loss; and
W and P are further optimized to minimize a peak temperature of the PCB.

11. A method of fabricating a rotary transformer (RT), the method comprising:
forming a printed circuit board (PCB); and
forming a set of secondary windings integrated with the PCB;
wherein the set of secondary windings comprises a plurality traces extending over a first region of the PCB and a second region of the PCB;
wherein the plurality of traces are organized in a first positional order in the first region of the PCB; and
wherein the plurality of traces are organized in a second positional order in the second region of the PCB.

12. The method of claim 11 wherein the PCB further comprises a first one of the plurality of traces.

13. The method of claim 12, wherein the first one of the plurality of traces has a first positional location in the first positional order.

14. The method of claim 13, wherein the first one of the plurality of traces has a second positional location in the second positional order.

15. The method of claim 14, wherein the first positional location in the first positional order is different from the second positional location in the second positional order.

16. The method of claim 15 further comprising forming a first via element of the PCB.

17. The method of claim 16, wherein a first end of the first via element is physically and electrically coupled to the first one of the plurality of traces in the first region.

18. The method of claim 17, wherein a second end of the first via element is physically and electrically coupled to the first one of the plurality of traces in the second region.

19. The method of claim 18, wherein:
the first region comprises a first layer of the PCB; and
the second region comprises a second layer of the PCB.

20. The method of claim 11, wherein:
each of the plurality of traces comprises a plurality of strands;
each of the plurality of strands comprises a width (W) and a position (P) within its associated trace;
W and P are optimized to minimize inductance loss; and
W and P are further optimized to minimize a peak temperature of the PCB.
